(19) United States
(12) Patent Application Publication
(10) Pub. No.: US 2004/0155244 A1
(43) Pub. Date: Aug. 12, 2004

(54) Transistor and method of manufacturing the same, electro-optical device, semiconductor device, and electronic apparatus

(75) Inventors: Hirotaka Kawata, Suwa-shi (JP); Masahiro Yasukawa, Chino-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/756,409

(22) Filed: Jan. 14, 2004

(30) Foreign Application Priority Data
Jan. 23, 2003 (JP) 2003-015100
Jul. 18, 2003 (JP) 2003-199207

(51) Int. Cl. H01L 29/04

(52) U.S. Cl. 257/59

(57) ABSTRACT

To provide a transistor having sufficient dielectric strength, including a gate insulating film which can be formed by easy processes, and not requiring a high-temperature crystallizing process, a method of manufacturing the transistor, and an electro-optical device, a semiconductor device, and an electronic apparatus including the transistor, a transistor includes at least a monocrystalline semiconductor layer and a gate insulating film provided on the monocrystalline semiconductor layer. The gate insulating film has a thermal oxide film formed on the monocrystalline semiconductor layer, and at least one vapor-deposited insulating film formed on the thermal oxide film.

### BACKGROUND OF THE INVENTION

1. Field of Invention

The present invention relates to a transistor having excellent dielectric strength properties and a method of manufacturing the transistor, and to an electro-optical device, a semiconductor device, and an electronic apparatus including the transistor.

2. Description of Related Art

In the related art, an SOI (Silicon On Insulator) substrate having a structure, in which a buried silicon oxide film and a monocrystalline silicon layer are sequentially stacked on a monocrystalline silicon substrate (or a quartz substrate), is known. When a transistor integrated circuit is fabricated in the monocrystalline silicon layer by using the SOI substrate having such structure, for example, a mesa type isolation method, as one of a plurality of methods of insulating and isolating the transistors from each other, is used. Since this isolation method, which is a method of removing all areas of the monocrystalline silicon layer other than an area in which the transistors should be formed, is characterized in that it is possible to easily manufacture the transistors and to narrow the isolating area, the isolation method is widely used. The transistors using the monocrystalline silicon layers isolated and formed by the above isolation method are used suitably as switching elements in various electro-optical devices.

When the transistors are formed using the aforementioned monocrystalline silicon layer, in the related art as shown in FIG. 15, the monocrystalline silicon layer 40 is thermally oxidized to form a thermal oxide film 41 composed of a silicon oxide film on the surface thereof, thereby using the thermal oxide film as a gate insulating film.

If such a thermal oxidation method is used, oxidation goes on relatively easily in a center portion of a surface direction of the monocrystalline silicon layer 40, and oxidation does not go on well in a peripheral portion thereof due to the diffusion conditions of oxidized species or an oxidation speed difference in crystal orientation. As a result, as shown in FIG. 15, the thermal oxide film 41 is formed to be thick in the center portion and is formed to be thin in the peripheral portion.

On the other hand, since the thermal oxidation goes on from side surfaces as well as the top surface of the above monocrystalline silicon layer 40, the thermal oxide film is thick in the center portions of the top surface and the side surfaces and is thin in the peripheral portions thereof, as shown in FIG. 15. Since a thinning in the top surface side and a thinning in the side surface side, all occur on an upper end portion, that is, a shoulder portion 41a of the monocrystalline silicon layer 40, the thickness of the thermal oxide film in the shoulder portion is much thinner than that in the other portions. The shoulder portion 40a of the monocrystalline silicon layer 40, which is an underlying layer of the thermal oxide film, is formed into a sharp and pointed shape.

As a result, an electric field is easily concentrated on the shoulder portion 40a, whereby a gate dielectric breakdown can easily occur in the shoulder portion 41a of the thermal oxide film 41 in the transistor.

In addition, another problem is that the transistor has a threshold voltage in the shoulder portion 40a (41a) smaller and smaller.

In order to address the above problems, a technology of forming the oxide film in the shoulder portion to be thicker than that in other portions is known in the related art. (See, for example, Japanese Unexamined Patent Application Publication No. 5-82789 and Japanese Unexamined Patent Application Publication No. 8-172198.

Further, specifically as a technology paying attention to the gate insulating film, a technology of forming a gate insulating film to have a multi-layered structure is known (See, for example, Japanese Unexamined Patent Application Publication No. 60-164362, Japanese Unexamined Patent Application Publication No. 63-1071, Japanese Unexamined Patent Application Publication No. 63-316479, Japanese Unexamined Patent Application Publication No. 2-65274, Japanese Unexamined Patent Application Publication No. 2-174230 and Japanese Unexamined Patent Application Publication No. 10-111521.

However, in Japanese Unexamined Patent Application Publication No. 5-82789 and Japanese Unexamined Patent Application Publication No. 8-172198, there are additional problems that a process for forming the oxide film of the shoulder portion to be thicker than other portions is complex, it is disadvantageous in cost, and satisfactory yield cannot be obtained, etc.

Further, for example, similar to a double gate structure shown in FIG. 16, when a plurality of gates 42 are formed on the monocrystalline silicon layer 40 by well-known methods such as “the film formation of gate material,” “patterning by etching,” there are problems that etching residuals 42a are generated in the peripheral edge portions of the monocrystalline silicon layer 40, and a short circuit is caused between the gate electrodes 42 due to the etching residuals 42a.

This is because the semiconductor layer constituting a channel region or source and drain regions is made of monocrystalline silicon, and thus the anisotropic etching speed thereof is larger than that of polycrystalline silicon, so that a lower end portion 41b of a side surface of the thermal oxide film 41 becomes extremely thin after the thermal oxidation, as shown in FIG. 17. That is, if the lower end portion 41b of the thermal oxide film 41 is extremely thin, the etching residuals 42a are easily generated under the lower portion 41b. As a result, a short circuit is generated between the gate electrodes 42 through the etching residuals 42a. Further, FIG. 17 illustrates a state in which the surface portion of the substrate 43, on which the monocrystalline silicon layer 40 is formed, is over-etched when a gate electrode material is etched. If the substrate 43 is over-etched in this way, the etching residuals 42a increase, so that a short circuit is easily generated between the gates 42.

In the remaining Japanese Unexamined Applications listed, the semiconductor layers constituting a channel region and source and drain regions are all made of polycrystalline silicon. When the channel region or the source and drain regions are formed of the polycrystalline silicon to manufacture a transistor, a crystallizing process for crystallizing the polycrystalline silicon layer should be performed at the high temperature of 1000° C. or more after the formation of the polycrystalline silicon layer. However, when such a high temperature process is performed, bending, etc. is generated due to a difference in thermal expansion coefficient between the polycrystalline silicon layer and a substrate on which the polycrystalline silicon layer is formed, and more seriously damages can be caused.

### SUMMARY OF THE INVENTION

The present invention is contrived to address the above problems, and thus the present invention provides a transistor having a sufficient dielectric strength, including a gate insulating film which can be formed through easy processes, and not requiring a high-temperature crystallizing process, a method of manufacturing the transistor, and an electro-optical device, a semiconductor device, and an electronic apparatus including the transistor.

In order to accomplish the above object, a transistor according to an aspect of the present invention includes a monocrystalline semiconductor layer in which a channel region and source and drain regions are formed, a gate insulating film provided on the monocrystalline semiconductor layer, and a gate electrode provided on the gate insulating film, the gate insulating film having a thermal oxide film formed on the monocrystalline semiconductor layer and at least one vapor-deposited insulating film formed on the thermal oxide film.

According to this transistor, since the semiconductor layer constituting the channel region and the source and drain regions is formed of the monocrystalline semiconductor layer, a high-temperature crystallizing process on the semiconductor layer is not required. Further, since the gate insulating film is constructed by forming the vapor-deposited insulating film on the thermal oxide film, in a shoulder portion of the monocrystalline semiconductor layer, the thermal oxide film is thinner than that of other portions, but the vapor-deposited insulating film formed thereon is not thinner than that of other portions and has a thickness equal to that of other portions. Therefore, from the viewpoint of a total thickness thereof, the shoulder portion does not become extremely thinner in comparison with other portions, and thus the efficient dielectric strength of the shoulder portion can be ensured. As a result, the gate dielectric breakdown of the shoulder portion can be reduced or prevented. Furthermore, since only a film formation process using a vapor deposition method is added to the process of forming the gate insulating film compared with the related art, the process is not complex, so that it is advantageous in cost and the decrease of yield can be suppressed.

Further, in the above transistor, it is preferable that the monocrystalline semiconductor layer be made of monocrystalline silicon.

By constructing the transistor as described above, the high-temperature process is unnecessary while a high-temperature process of 1000° C. or more is necessary in he related art for the crystallization thereof, for example, when a “polycrystalline silicon layer,” which is a polycrystalline semiconductor layer, is used instead of the “monocrystalline semiconductor layer.” Thus, it is possible to reduce or prevent disadvantages, such as the bending or damage described above.

Furthermore, in the above transistor, it is preferable that the monocrystalline semiconductor layer be a mesa type.

In this way, since the monocrystalline semiconductor layer can be easily formed and the isolating areas can be formed narrow, the transistor using the monocrystalline semiconductor layer can be suitably used, for example, as a switching element in various electro-optical devices.

Furthermore, in the above transistor, it is preferable that the monocrystalline semiconductor layer have a thickness of 15 to 60 nm.

As a result, since the thickness of the monocrystalline semiconductor layer is 15 nm or more, the forming of contact holes, etc. in the monocrystalline semiconductor layer can be performed without any difficulty. In addition, when the transistor is used, for example, as a switching element of an electro-optical device, leakage current through the monocrystalline semiconductor layer can decrease sufficiently since the thickness of the monocrystalline semiconductor layer is 60 nm or less.

Furthermore, in the above transistor, it is preferable that the thermal oxide film of the gate insulating film have a thickness of 5 to 50 nm.

Accordingly, since the thickness is 50 nm or less, a thermal load in forming the thermal oxide film is reduced, and thus defects due to the thermal load can be reduced or prevented from being generated. Furthermore, even if the thickness is 5 nm or less, it is currently difficult to form the thin film with a good film quality and with a predetermined thickness.

A method of manufacturing a transistor according to an aspect of the present invention is a method of manufacturing a transistor in which a channel region and source and drain regions are formed in a monocrystalline semiconductor layer and a gate electrode is formed with a gate insulating film therebetween on the monocrystalline semiconductor layer, and the method includes a step of forming the gate insulating film, the step of forming the gate insulating film including at least a step of thermally oxidizing the monocrystalline semiconductor layer to form a thermal oxide film on a surface thereof and a step of forming a vapor-deposited insulating film on the thermal oxide film using a vapor deposition method.

According to the method of manufacturing a transistor, as described above, since the semiconductor layer constituting the channel region and the source and drain regions is formed of the monocrystalline semiconductor layer, a high-temperature crystallizing process on the semiconductor layer is not required. Further, since the gate insulating film is constructed by forming the vapor-deposited insulating film on the thermal oxide film as described above, a shoulder portion thereof does not become extremely thinner than other portions, and thus the sufficient dielectric strength of the shoulder portion can be ensured. Thus, the gate dielectric breakdown of the shoulder portion can be reduced or prevented. Furthermore, since only a film formation process using a vapor deposition method is added to the process of forming the gate insulating film compared with the related art, the process is not complex, so that it is advantageous in cost and the decrease of yield can be suppressed.

Furthermore, in the above method of manufacturing a transistor, it is preferable that the step of thermally oxidizing the monocrystalline semiconductor layer to form the thermal oxide film on the surface thereof be carried out by using both a dry thermal oxidation process and a wet thermal oxidation process.

As a result, when the thickness of the thermal oxide film to be formed is thin to the extent of 10 nm or less and it is difficult to control the thickness only by the dry thermal oxidation process, a thermal oxidation temperature is lowered and a thermal oxidation speed is made to be delayed by the wet thermal oxidation process. Thus, it is possible to control the thickness, and it is also possible to reduce defects to be generated.

An electro-optical device according to an aspect of the present invention includes the transistor or the transistor obtained by the above manufacturing method.

Since this electro-optical device includes the transistor of which the gate dielectric breakdown is reduced or prevented, of which the manufacturing process is simple to be advantageous in cost, and of which the decrease of yield is suppressed, the electro-optical device has high reliability, an advantage in cost, and excellent productivity.

Another electro-optical device according to an aspect of the present invention is an electro-optical device in which an electro-optical material is interposed between a pair of substrates facing each other, the above transistor, or the transistor obtained by the above manufacturing method, being provided as a switching element in a display area.

Since this electro-optical device includes as a switching element the transistor in which the gate dielectric breakdown is reduced or prevented, of which the manufacturing process is simple to be advantageous in cost, and of which the decrease of yield is suppressed, the electro-optical device has high reliability, an advantage in cost, and excellent productivity.

A semiconductor device according to an aspect of the present invention includes the transistor or the transistor obtained by the above manufacturing method.

Since this semiconductor device includes the transistor of which the gate dielectric breakdown is reduced or prevented, of which the manufacturing process is simple to be advantageous in cost, and of which the decrease of yield is suppressed, the semiconductor device has high reliability, an advantage in cost, and excellent productivity.

An electronic apparatus according to an aspect of the present invention includes the above electro-optical device or the above semiconductor device.

Since this electronic apparatus includes a device having the transistor of which the gate dielectric breakdown is reduced or prevented, of which the manufacturing process is simple to be advantageous in cost, and of which the decrease of yield is suppressed, the electronic apparatus has high reliability, an advantage in cost, and excellent productivity.

### BRIEF DESCRIPTION OF THE DRAWINGS

FIG. 1 is a plan view illustrating a liquid crystal panel as an example of an electro-optical device according to an aspect of the present invention;

FIG. 2 is a cross-sectional view taken along the plane A-A′ of FIG. 1;

FIG. 3 is a cross-sectional view taken along the plane B-B′ of FIG. 1;

FIGS. 4A to 4C are views illustrating exemplary processes of manufacturing the electro-optical device;

FIGS. 5A and 5B are views illustrating exemplary processes of manufacturing the electro-optical device;

FIGS. 6A to 6D are views illustrating exemplary processes of manufacturing the electro-optical device.

FIGS. 7A and 7B are views illustrating exemplary processes of manufacturing the electro-optical device.

FIGS. 8A to 8D are views illustrating exemplary processes of manufacturing the electro-optical device.

FIGS. 9A to 9E are views illustrating exemplary processes of manufacturing the electro-optical device.

FIGS. 10A to 10D are views illustrating exemplary processes of manufacturing the electro-optical device.

FIGS. 11A to 11C are views illustrating exemplary processes of manufacturing the electro-optical device.

FIGS. 12A to 12C are views illustrating exemplary processes of manufacturing the electro-optical device.

FIGS. 13A and 13B are enlarged views of an important part in an exemplary process of forming a gate insulating film.

FIG. 14 is a view illustrating an example of a mobile phone as an electronic apparatus.

FIG. 15 is a cross-sectional view of an important part of a related art gate insulating film comprising a thermal oxide film.

FIG. 16 is a plan view schematically illustrating a double gate structure.

FIG. 17 is a cross-sectional view of an important part illustrating related art problems.

### DETAILED DESCRIPTION OF EXEMPLARY EMBODIMENTS

Now, the present invention will be described in detail.

Method of Manufacturing an Electro-Optical Device

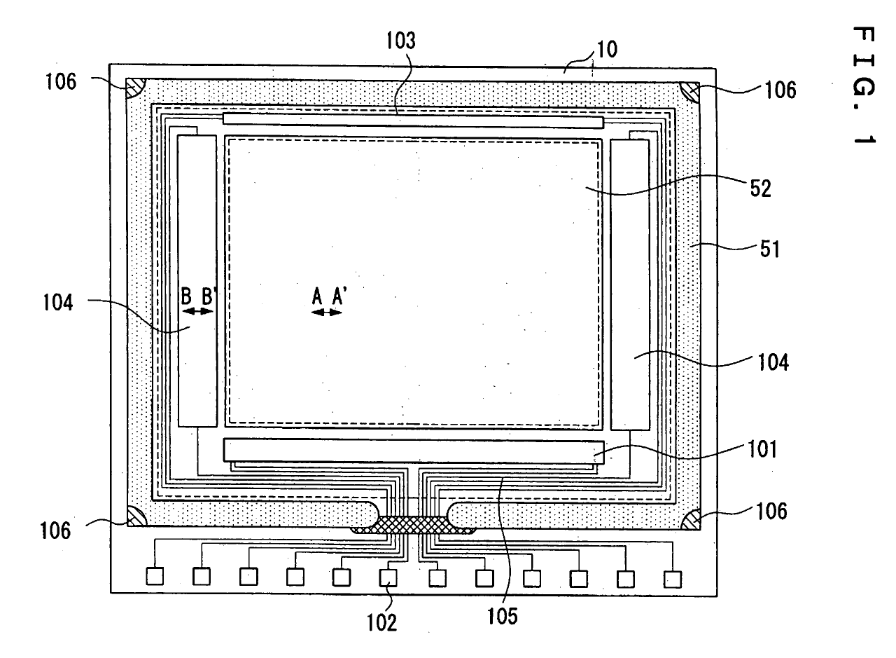

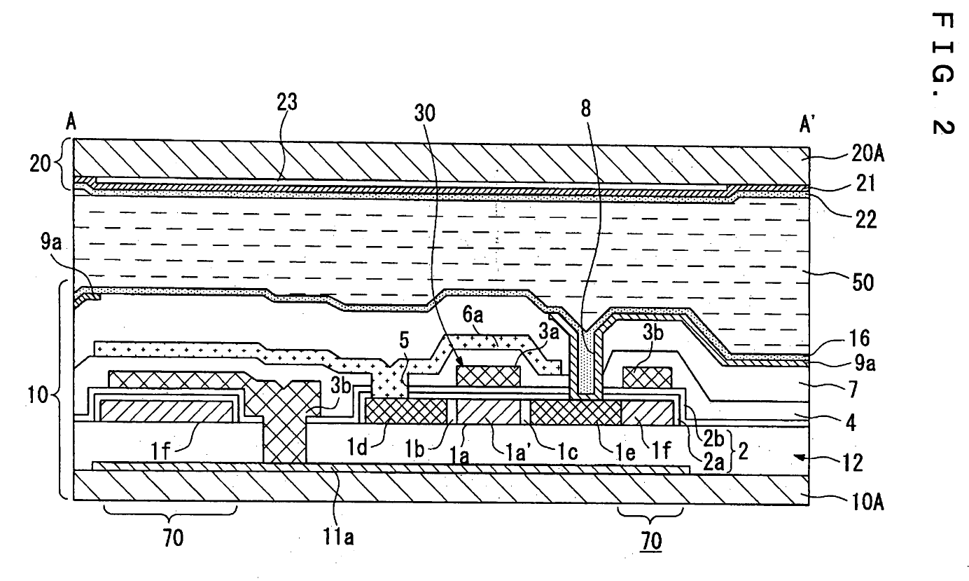

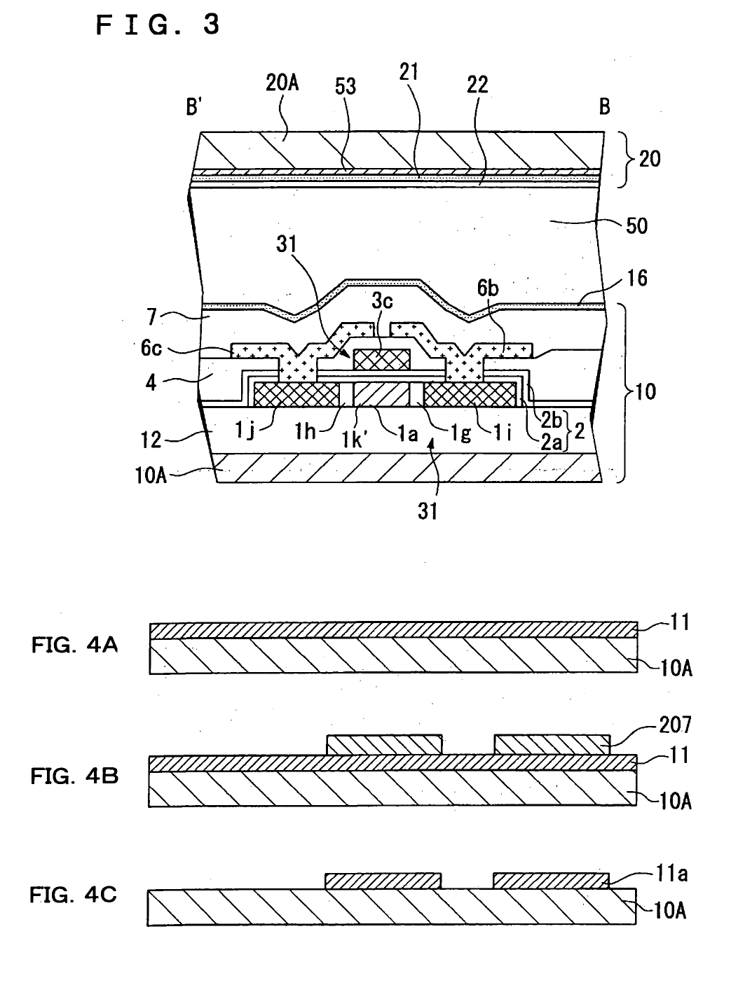

First, one exemplary embodiment, in which an electro-optical device according to an aspect of the present invention is applied to a liquid crystal panel, will be described. FIG. 1 is a plan view illustrating the entire construction of a liquid crystal panel, which is an exemplary embodiment of an electro-optical device according to an aspect of the present invention, and also a plan view illustrating a TFT array substrate with various components formed thereon as seen from a counter substrate. FIG. 2 is a cross-sectional view taken along the plane A-A′ of FIG. 1. FIG. 3 is a cross-sectional view taken along the plane B-B′ of FIG. 1.

The liquid crystal panel (electro-optical device) shown in FIGS. 1, 2 and 3, in which liquid crystal is injected and sealed between a pair of substrates, includes a thin film transistor (hereinafter, abbreviated as “TFT”) array substrate 10 constituting one substrate, and a counter substrate 20 constituting the other substrate provided to be opposite thereto.

FIG. 1 illustrates the TFT array substrate 10 with various components formed thereon. As shown in FIG. 1, on the TFT array substrate 10, a seal material 51 is provided along edges thereof, and a light-shielding film (not shown in FIG. 1) as a frame is provided inside the seal material 51 in parallel to the seal material 51. Further, in FIG. 1, a reference numeral 52 indicates a display area. Further, the display area 52, which is positioned inside the light-shielding film as a frame, is an area used for the display of the liquid crystal panel. Furthermore, the outside of the display area is a non-display area (not shown).

In the non-display area, a data line driving circuit 101 and external circuit connection terminals 102 are provided along one side of the TFT array substrate 10, scanning line driving circuits 104 are provided along two sides adjacent to the one side, and a pre-charge circuit 103 is provided along the remaining side. Furthermore, a plurality of wiring lines 105 to connect the data line driving circuit 101, the pre-charge circuit 103, the scanning line driving circuits 104, and the external circuit connection terminals 102 each other are provided.

Electrical connection materials 106 to electrically connect the TFT array substrate 10 with the counter substrate 20 are provided at positions corresponding to corner portions of the counter substrate 20. Further, the counter substrate 20 having a shape substantially equal to the seal material 51 is attached to the TFT array substrate 10 through the seal material 51.

As shown in FIGS. 2 and 3, the TFT array substrate 10 includes, as main components, a substrate body 10A formed of an light-permeable insulating substrate, such as quartz, pixel electrodes 9a formed on a surface of a liquid crystal layer 50 side thereof and formed of a transparent conductive film, such as an ITO (Indium Tin Oxide) film, pixel switching TFTs (switching elements) 30 provided in the display area, TFTs (switching elements) 31 for driving circuits provided in the non-display area, and an alignment film 16 which is formed of an organic film, such as a polyimide film, and on which a predetermined alignment process, such as a rubbing process, has been carried out. The pixel switching TFTs (switching elements) 30 and the TFTs (switching elements) 31 for driving circuits are examples of transistors according to an aspect of the present invention as described later.

On the other hand, the counter substrate 20 includes, as main components, a substrate body 20A formed of a light-permeable substrate, such as transparent glass or quartz, a counter electrode 21 formed on a surface of the liquid crystal layer 50 side thereof, an alignment film 22, a light-shielding film 23 made of metal and provided in an area other than the opened areas of pixel portions, and a light-shielding film 53 as a frame made of a material equal to or different from the light-shielding film 23.

The liquid crystal layer 50 is formed between the TFT array substrate 10 and the counter substrate 20 constructed as above and arranged such that the pixel electrodes 9a are opposite to the counter electrode 21.

As shown in FIG. 2, on the surface of the liquid crystal layer 50 side of the substrate body 10A of the TFT array substrate 10, light-shielding layers 11a are provided at positions corresponding to the pixel switching TFTs 30. In addition, a first interlayer insulating film 12 is provided between the light-shielding layers 11a and the plurality of pixel switching TFTs 30. The first interlayer insulating film 12 is provided to electrically insulate a semiconductor layer 1a constituting the pixel switching TFTs 30 from the light-shielding layers 11a.

As shown in FIGS. 2 and 3, the pixel switching TFTs 30 and the TFTs 31 for driving circuits, which are transistors according to an aspect of the present invention, have an LDD (Lightly Doped Drain) structure, and they include a channel region 1a of the semiconductor layer 1a in which a channel is formed due to an electric field from a scanning line 3a, a channel region 1k′ of the semiconductor layer 1a in which a channel is formed due to an electric field from a gate electrode 3c, a gate insulating film 2 to insulate the semiconductor layer 1a from the scanning line 3a and the gate electrode 3c, a data line 6a, lightly doped source regions 1b and 1g, and lightly doped drain regions 1c and 1h of the semiconductor layer 1a, and heavily doped source regions 1d and 1i (source regions) and heavily doped drain regions 1e and 1j (drain regions) of the semiconductor layer 1a.

Here, the semiconductor layer 1a is made of monocrystalline silicon. The thickness of the semiconductor layer 1a is preferably 15 nm or more, and in this case, more preferably 15 to 60 nm. If the thickness is less than 15 nm, it may have a bad influence on a process of forming contact holes to connect the pixel electrodes 9a with the switching elements 30 and 31. If the thickness is more than 60 nm, light from a light source or reflected light may be incident on the semiconductor layer 1a, so that longitudinal crosstalk may occur and have a bad influence on a display performance. That is, when the thickness is limited to 60 nm or less, it is possible to decrease leakage current due to light leakage by one cipher compared with a case where the thickness is, for example, 200 nm.

In this exemplary embodiment, the gate insulating film 2 has a stacked structure, that is, a stacked structure of the thermal oxide film (silicon oxide film) 2a and the vapor-deposited insulating film 2b. The thickness of the thermal oxide film 2a is about 5 to 50 nm, and preferably about 5 to 30 nm. Specifically, when the thickness of the semiconductor layer 1a is in the range of 15 to 60 nm as described above, the thickness of the thermal oxide film 2a is about 5 to 50 run, preferably about 5 to 20 nm, and more specifically about 5 to 10 nm. Since defects due to heat stress are easily generated in forming the thermal oxide film 2a of the gate insulating film 2 when the thickness of the semiconductor layer 1a is formed to be thin to the extent of 60 nm or less, the lower limit value of the thickness of the thermal oxide film 2a is set to be 5 nm and the upper limit value thereof is as small as possible in order to reduce the thermal load in the thermal oxidation as much as possible.

Even if the thickness of the thermal oxide film 2a is intended to be 5 nm or less, it is currently difficult to form the thermal oxide film with a good film quality and with a predetermined thickness, so that the lower limit value of the thickness of the thermal oxide film 2a is set to 5 nm.

When the semiconductor layer 1a is formed to be a thin film having a thickness of 60 nm or less, the stress to be applied to the thin film in the thermal oxidation increases inversely corresponding to the thickness, compared with a case where the thickness is, for example, 200 nm. Thus, the stress is not reduced, so that defects are easily generated in the thin film. Therefore, by setting the thickness of the thermal oxide film 2a to be thin to shorten a thermal oxidation time or lower a thermal oxidation temperature in forming the thermal oxide film 2a, the thermal stress to be applied to the semiconductor layer 1a is reduced to reduce or prevent defects from being generated.

Furthermore, in forming the thermal oxide film 2a, specifically when the thickness thereof is set to be thin to the extent of, for example, 10 nm or less, it is preferable that the thermal oxidation of the semiconductor layer 1a be carried out by using both a dry thermal oxidation process and a wet thermal oxidation process.

That is, if the thickness of the thermal oxide film 2a to be formed is set to, for example, 20 nm, in a case where the dry thermal oxidation process of 1000° C. is carried out as the thermal oxidation, the processing time can be set to be relatively short to the extent of 18 minutes, so that the number of defects generated can decrease. However, if the thickness of the thermal oxide film 2a is intended to be smaller, it is difficult to control the thickness in the dry thermal oxidation at that temperature.

Therefore, when the thickness of the thermal oxide film 2a to be formed is set to, for example, 10 nm, it is possible to decrease the number of defects by carrying out the dry thermal oxidation process of 900° C. as the thermal oxidation for 30 minutes. Alternatively, by carrying out the wet thermal oxidation process of 750° C. for 30 minutes, it is possible to considerably decrease the number of defects. Specifically, as compared with a case where the dry thermal oxidation process of 1000° C. is carried out the number of defects can decrease to 1/10 or less in a case where the dry thermal oxidation process of 900° C. is carried out. Further, as compared with a case where the dry thermal oxidation process of 1000° C. is carried out, the number of defects can decrease to 1/100 or less in a case where the wet thermal oxidation process of 750° C. is carried out.

In this way, in a case where the thickness of the thermal oxide film 2a is, for example, 10 nm and it is difficult to control the thickness using only the dry thermal oxidation process, the wet thermal oxidation process can be specifically used to lower the thermal oxidation temperature and to decrease the thermal oxidation speed as much. As a result, it is possible to control the thickness and to decrease the thermal load, so that it is possible to reduce the defects to be generated.

That the thermal oxidation of the semiconductor layer 1a is performed by using both the dry thermal oxidation process and the wet thermal oxidation process means that the dry thermal oxidation process and the wet thermal oxidation process are suitably switched for use in accordance with the set thickness of the thermal oxide film 2a.

On the other hand, the vapor-deposited insulating film 2b, which is formed by a CVD method as described later, is formed of one or more films selected from a silicon oxide film, a silicon nitride film, a silicon oxy-nitride film, etc. The thickness of the vapor-deposited insulating film 2b (a total thickness when two or more kinds of films are formed) is 10 nm or more. Further, the total thickness of the gate insulating film 2, that is, the sum thickness of the thermal oxide film 2a and the vapor-deposited insulating film 2b is set to about 60 to 80 nm. This is because the aforementioned range of thickness is necessary to ensure the dielectric strength, specifically in a case where the driving voltage of the pixel switching TFTs 30 or the TFTs 31 for driving circuits is set to about 10 to 15V.

Furthermore, when a high-permittivity material, such as a silicon nitride film or a silicon oxy-nitride film, is selected for use as the vapor-deposited insulating film 2b, a large quantity of current can be obtained, so that it is possible to reduce a transistor size. On the other hand, when a silicon oxide film is selected for use as the vapor-deposited insulating film 2b, it is formed of the same material as the thermal oxide film 2a, which is an underlying layer thereof, so that an etching process can be easily carried out in forming contact holes communicating with the semiconductor layer 1.

In this liquid crystal panel, as shown in FIG. 2, by making the gate insulating film 2 extend from a position facing the scanning line 3a for use as a dielectric film, making the semiconductor film 1a extend for use as a first storage capacitor electrode 1f, and using a part of a capacitor line 3b facing them as a second storage capacitor electrode, a storage capacitor 70 is constructed. The capacitor line 3b and the scanning line 3a are formed of the same poly silicon film, or a stacked structure of the poly silicon film and a simple metal substance, an alloy, metal silicide, etc., and the dielectric film of the storage capacitor 70, and the gate insulating film 2 of the pixel switching TFT 30 and the TFT 31 for the driving circuit are formed of the same high-temperature oxide film. Further, a channel region 1a′, a source region 1d, and a drain region 1e of the pixel switching TFT 30, a channel region 1k′, a source region 1i, and a drain region 1j of the TFT 31 for the driving circuit, and the first storage capacitor electrode 1f are formed of the same semiconductor layer 1a. The semiconductor layer 1a, which is made of monocrystalline silicon as described above, is provided in the TFT array substrate 10 to which the SOI (Silicon On Insulator) technology is applied.

Furthermore, as shown in FIG. 2, a second interlayer insulating film 4 is formed on the scanning line 3a, the gate insulating film 2, and the first interlayer insulating film 12. A contact hole 5 communicating with the heavily doped source region 1d of the pixel switching TFT 30, and a contact hole 8 communicating with the heavily doped drain region 1e of the pixel switching TFT 30 are formed in the second interlayer insulating film 4, respectively. A third interlayer insulating film 7 is formed on the data line 6a and the second interlayer insulating film 4, and a contact hole 8 communicating with the heavily doped drain region 1e of the pixel switching TFT 30 is formed in the third interlayer insulating film 7. The pixel electrode 9a is provided on the third interlayer insulating film 7 constructed as above.

On the other hand, as shown in FIG. 3, the pixel electrode 9a is not connected to the TFT 31 for the driving circuit, a source electrode 6b is connected to the source region of the TFT 31 for the driving circuit, and a drain electrode 6c is connected to the drain region 1j of the TFT 31 for the driving circuit.

Next, a method of manufacturing a transistor according to an aspect of the present invention will be described based on the method of manufacturing the liquid crystal panel (electro-optical device) constructed as above.

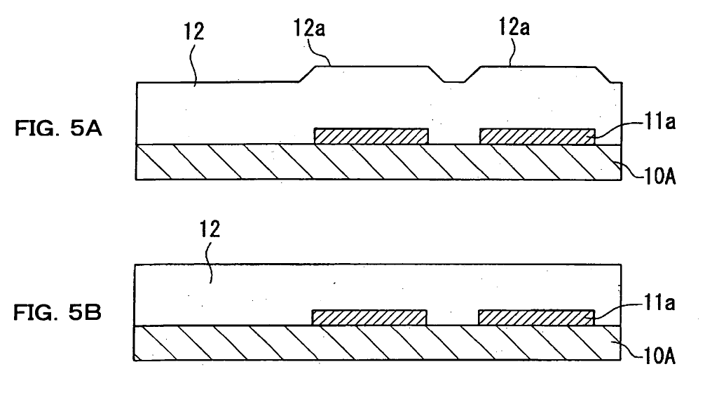

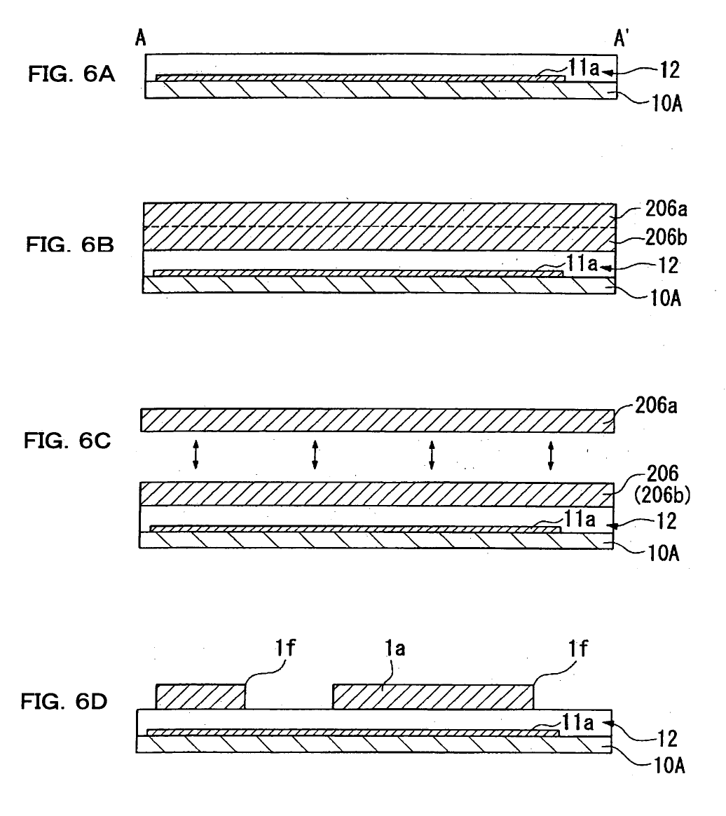

With reference to FIGS. 4 to 12, a method of manufacturing the TFT array substrate 10 in the method of manufacturing the liquid crystal panel shown in FIGS. 1, 2, and 3 will be first described. On the other hand, FIG. 4, FIG. 5, and FIGS. 6 to 12 are shown in different reduced scales.

With reference to FIGS. 4 and 5, a process of forming the light-shielding layer 11a and the first insulating film 12 on the surface of the substrate body 10A of the TFT array substrate 10 will be first described in detail. Furthermore, FIGS. 4 and 5 are process views illustrating a part of the TFT array substrate in each step correspondingly to the cross-sectional view of the liquid crystal panel shown in FIG. 2.

First, a permeable substrate body 10A, such as a quartz substrate, a hard glass, and the like, is prepared.

Then, it is preferable that the substrate body 10A be annealed at a high temperature of preferably about 850 to 1300° C., more preferably about 1000° C. under an inert gas atmosphere such as N2 (nitrogen), and then the substrate body 10A be previously processed to be subject to less distortion in a high-temperature process to be carried out thereafter. That is, it is preferable that the substrate body 10A be subjected to a heat treatment of the temperature equal to or more than the highest temperature in the manufacturing process.

As shown in FIG. 4(A), a light-shielding material layer 11 with a thickness of 150 to 200 nm is formed by depositing a simple metal substance, an alloy, metal silicide, etc. including at least one of Ti, Cr, W, Ta, Mo, and Pb on the entire surface of the substrate body 10A processed as above using a sputtering method, a CVD method, an electron-beam heating deposition method, and the like.

Next, a photo resist is formed on the entire surface of the substrate body 10A, and then the photo resist is exposed using a photo mask having a pattern of the light-shielding layer 11a to be finally formed. Thereafter, by developing the photo resist, a photo resist 207 having the pattern of the light-shielding layer 11a to be finally formed is formed, as shown in FIG. 4B.

Next, by etching the light-shielding material layer 11 using the photo resist 207 as a mask and then by removing the photo resist 207, the light-shielding layer 1a having a predetermined pattern (see FIG. 2) is formed in an area, in which the pixel switching TFT 30 should be formed, on the surface of the substrate body 10A as shown in FIG. 4C. The thickness of the light-shielding layer 11a is, for example, about 150 to 200 nm.

Next, as shown in FIG. 5A, the first interlayer insulating film 12 is formed on the surface of the substrate body 10A on which the light-shielding layer 11a is formed, by the sputtering method, the CVD method, and the like. At that time, on the area in which the light-shielding layer 11a is formed, a convex portion 12a is formed on the surface of the first interlayer insulating film 12. As a material of the first interlayer insulating film 12, silicon oxide or glass of high dielectric strength, such as NSG (Non-doped Silicate Glass), PSG (Phosphosilicate Glass), BSG (Borosilicate Glass), BPSG (Borophosphosilicate Glass), and the like, can be exemplified.

Next, by polishing the surface of the first interlayer insulating film 12 using a CMP (Chemical Mechanical Polishing) method, etc. to remove the convex portion 12a as shown in FIG. 5B, the surface of the first interlayer insulating film 12 is flattened. The thickness of the first interlayer insulating film 12 is preferably about 400 to 1000 m, and more preferably about 800 run.

Next, referring to FIGS. 6 to 12, a method of forming the TFT array substrate 10 out of the substrate body 10A, on which the first interlayer insulating film 12 is formed, will be described. FIGS. 6 to 12 are process views illustrating a part of the TFT array substrate in each process correspondingly to the cross-sectional view of the liquid crystal panel shown in FIG. 2.

FIG. 6A is a view in which a part of FIG. 5B is extracted and illustrated in a different reduced scale.

As shown in FIG. 6B, the substrate body 10A, shown in FIG. 6A, which has the flattened first interlayer insulating film 12, and a monocrystalline silicon substrate 206a are bonded to each other.

The thickness of the monocrystalline silicon substrate 206a used in the bonding is, for example, about 600 mm. An oxide film layer 206b is formed in advance on a surface of the monocfystalline silicon substrate 206a, which is bonded to the substrate body 10A, and hydrogen ions (H+) are implanted also in advance thereto, for example, with a dose of 10′1016/cm2 and an accelerating voltage 100 keV. The oxide film layer 206b is formed by oxidizing the surface of the monocrystalline silicon substrate 206a by a thickness of about 0.05 to 0.8 mm.

A method of directly bonding two substrates by heating them, for example, at a temperature of 300° C. for two hours can be used as a bonding process.

In order to further enhance a bonding strength, it is required that the heating temperature rises up to 450° C., but since a thermal expansion coefficient of the substrate body 10A made of quartz, etc. is largely different from a thermal expansion coefficient of the monocrystalline silicon substrate 206a, such heating causes defects, such as cracks in the monocrystalline silicon layer, so that the quality of the TFT array substrate 10 to be manufactured can deteriorate. In order to suppress the generation of defects, such as cracks, it is preferable that the monocrystalline silicon substrate 206a having been once subjected to the heating process of 300° C. for the bonding be made to be thinner to 100 to 150 mm by a wet etching or the CMP method and then is subjected to a higher-temperature heating process. For example, it is preferable that by etching the monocrystalline silicon substrate 206a to a thickness of 150 mm using a KOH aqueous solution of 80° C., bonding the etched substrate to the substrate body 10A, and then heating the bonded substrates again at a temperature of 450° C., the bonding strength be enhanced.

Next, as shown in FIG. 6C, a heating process to peel off (separate) the monocrystalline silicon substrate 206a from the substrate body 10A is carried out, with the oxide film layer 206b of the bonding surface side of the bonded monocrystalline silicon substrate 206a and the monocrystalline silicon layer 206 left.

The peeling-off of the substrate is caused because the bonding between silicon atoms in a layer close to the surface of the monocrystalline silicon substrate 206a is released due to hydrogen ions introduced into the monocrystalline silicon substrate 206a. The heating process can be carried out by heating the two bonded substrates, for example, at a rising speed of 20° C. per minute up to 600° C. The bonded monocrystalline silicon substrate 206a is separated from the substrate body 10A by this heating process, so that the monocrystalline silicon layer 206 having a thickness of about 200 nm±5 nm is formed on the surface of the substrate body 10A.

The monocrystalline silicon layer 206 can be formed to have any thickness within a range of, for example, 10 to 3000 nm by varying the accelerating voltage of hydrogen ion implantation on the above monocrystalline silicon substrate 206a.

Furthermore, the thinned monocrystalline silicon layer 206 may be obtained by a method of polishing the surface of the monocrystalline silicon substrate to a thickness of 3 to 5 mm and then etching it to a thickness of 0.05 to 0.8 mm using a PACE (Plasma Assisted Chemical Etching) method, or an ELTRAN (Epitaxial Layer Transfer) method of transferring an epitaxial silicon layer formed on a porous silicon substrate onto a bonding substrate through a selective etching of the porous silicon layer, in addition to the method described above.

In order to enhance the adhesion between the first interlayer insulating film 12 and the monocrystalline silicon layer 206 and to increase the bonding strength, it is preferable that the substrate body 10A and the monocrystalline silicon layer 206 be bonded to each other and that then they be subjected to a heating process using a rapid thermal annealing (RTA) method. The heating temperature of 600 to 1200° C. is preferable, but in order to lower the viscosity of the oxide film and to enhance the adhesion between atoms, it is preferable that the heating temperature be about 1050 to 1200° C.

Next, as shown in FIG. 6D, the semiconductor layer 1a having a predetermined pattern is formed by a mesa type isolation method using a photolithography process, an etching process, etc. Specifically, the first storage capacitor electrode 1f extending from the semiconductor layer 1a constituting the pixel switching TFT 30 is formed in an area in which the capacitor line 3b is formed under the data line 6a and in an area in which the capacitor line 3b is formed along the scanning line 3a. A well-known LOCOS isolation method, or a trench isolation method may be used as the element isolation process.

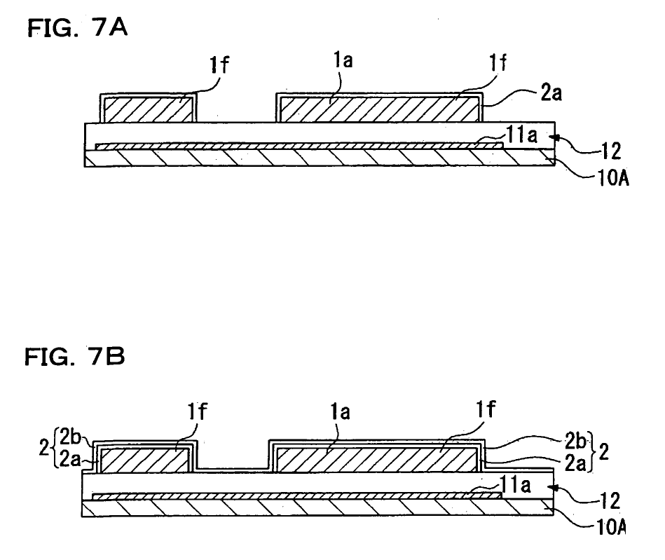

Next, as shown in FIG. 7A, by thermally oxidizing the semiconductor layer 1a at a temperature of about 750 to 1050° C., the thermal oxide film (silicon oxide film) 2a having a thickness of 5 to 50 nm is formed as described above. Here, the dry thermal oxidation process or the wet thermal oxidation process is suitably selected and used as the thermal oxidation method in accordance with the thickness of the thermal oxide film 2a to be formed as described above.

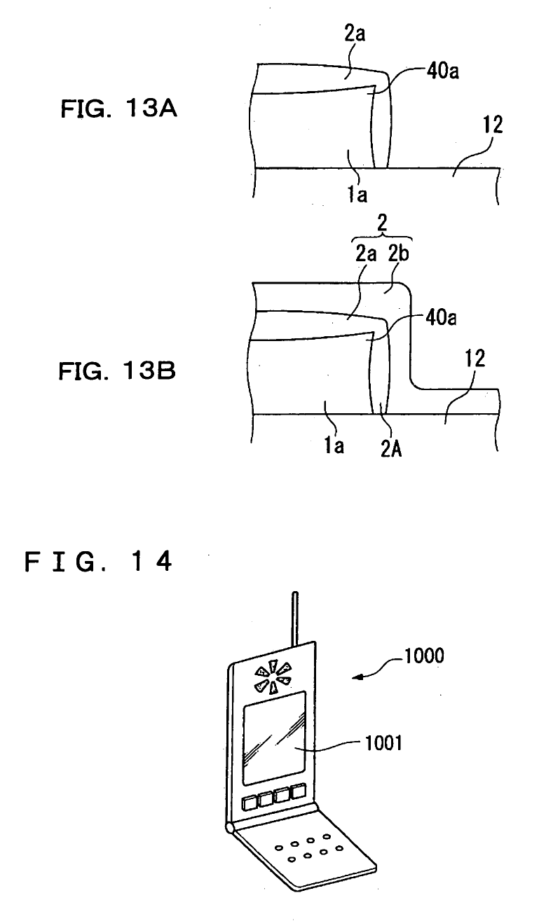

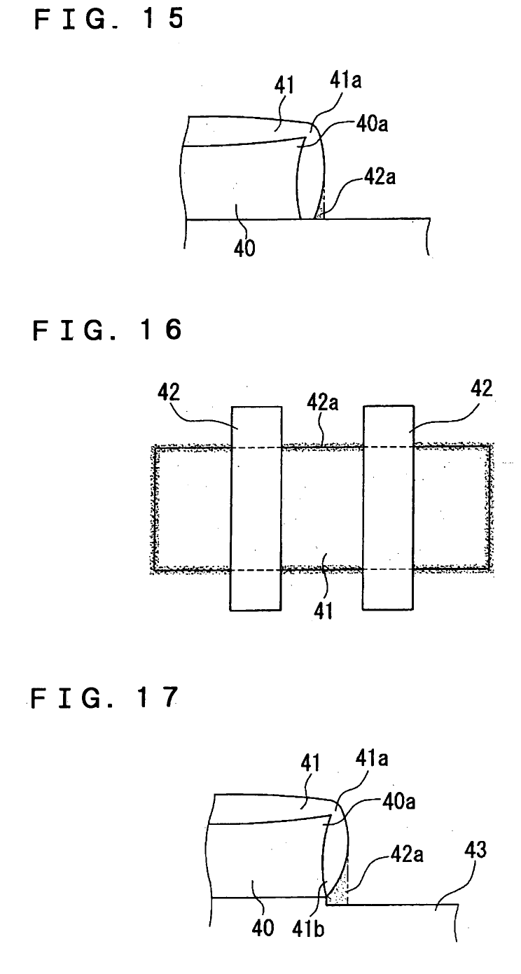

At that time, the obtained thermal oxide film 2a is formed thinly on a shoulder portion 40a of the semiconductor layer 1a as shown in FIG. 13A. However, in an aspect of the present invention, since the thermal oxide film 2a is formed thinner than the related art thermal oxide film, a difference in thickness between the shoulder portion 40a and the other portions is smaller than the related art one shown in FIG. 15.

Next, as shown in FIG. 7B, by depositing silicon oxide, silicon nitride or silicon oxy-nitride using a vapor deposition method, such as a normal pressure or low pressure CVD method, a deposition method to form a film, the vapor-deposited insulating film 2b is formed. Accordingly, since the vapor-deposited insulating film 2b is formed on the thermal oxide film 2a and the first interlayer insulating film 12 into an almost uniform thickness, the thickness on the shoulder portion 40a of the semiconductor layer 1a is equal to that of the other portions as shown in FIG. 133B. Therefore, the gate oxide film 2 according to an aspect of the present invention including the thermal oxide film 2a and the vapor-deposited insulating film 2b is not extremely thinner on the shoulder portion 40a than on the other portions, so that sufficient dielectric strength can be ensured on the shoulder portion 40a.

Furthermore, the vapor-deposited insulating film 2b may be formed into a single layer, or into a stacked layer of two kinds or more selected from the aforementioned insulating materials. Further, the thickness thereof is 10 run or more as described above. This is because a high-quality film cannot be obtained if it is intended to be less than 10 nm.

In this way, by carrying out the annealing process at a temperature of about 900 to 1050° C. under an inert gas atmosphere, for example, under a nitrogen or argon gas atmosphere after forming the thermal oxide film 2a and the vapor-deposited insulating film 2b, respectively, the gate oxide film 2 having a stacked structure of the thermal oxide film 2a and the vapor-deposited insulating film 2b is obtained. Here, it is preferable that the thickness of the gate oxide film 2, that is, a total thickness of the thermal oxide film 2a and the vapor-deposited insulating film 2b be about 60 to 80 nm as described above.

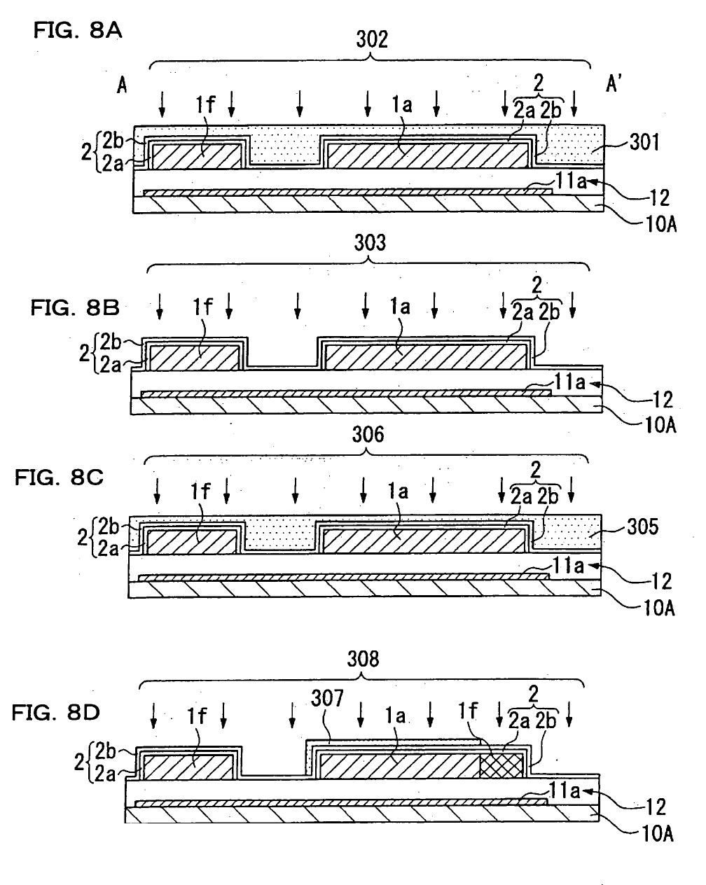

Next, as shown in FIG. 8A, a resist film 301 is formed at the position corresponding to the N channel semiconductor layer 1a while dopants 302 of Group V element, such as P (phosphorous) are doped into the P channel semiconductor layer 1a (not shown) with a low concentration (for example, P ions with an accelerating voltage of 70 keV and a dose of 2′ 1011/cm2).

Next, as shown in FIG. 8B, a resist film is formed at the position corresponding to the P channel semiconductor layer 11a (not shown) while dopants 303 of Group III element, such as B (boron), are doped into the N channel semiconductor layer 1a with a low concentration (for example, B ions with an accelerating voltage of 35 keV and a dose of 2′ 1012/cm2).

Next, as shown in FIG. 8C, a resist film 305 is formed on the surface of the substrate 10. Then, dopants 306 of Group V element, such as P, are doped into the P channel with a dose about one to ten times that in the process shown in FIG. 8A, and dopants 306 of Group III element, such as B, are doped into the N channel with a dose about one to ten times that in the process shown in FIG. 8B, respectively.

Next, as shown in FIG. 8D, in order to decrease the resistance of the first storage capacitor electrode 1f extending from the semiconductor layer 1a, a resist film 307 (having a width larger than that of the scanning line 3a) is formed in the portion on the surface of the substrate body 10A corresponding to the portion other than the first storage capacitor electrode 1f, and then by using the resist film as a mask, dopants 308 of Group V element, such as P, are doped from the upside thereof with a low concentration (for example, P ions with an accelerating voltage of 70 keV and a dose of 3′ 1014/cm2).

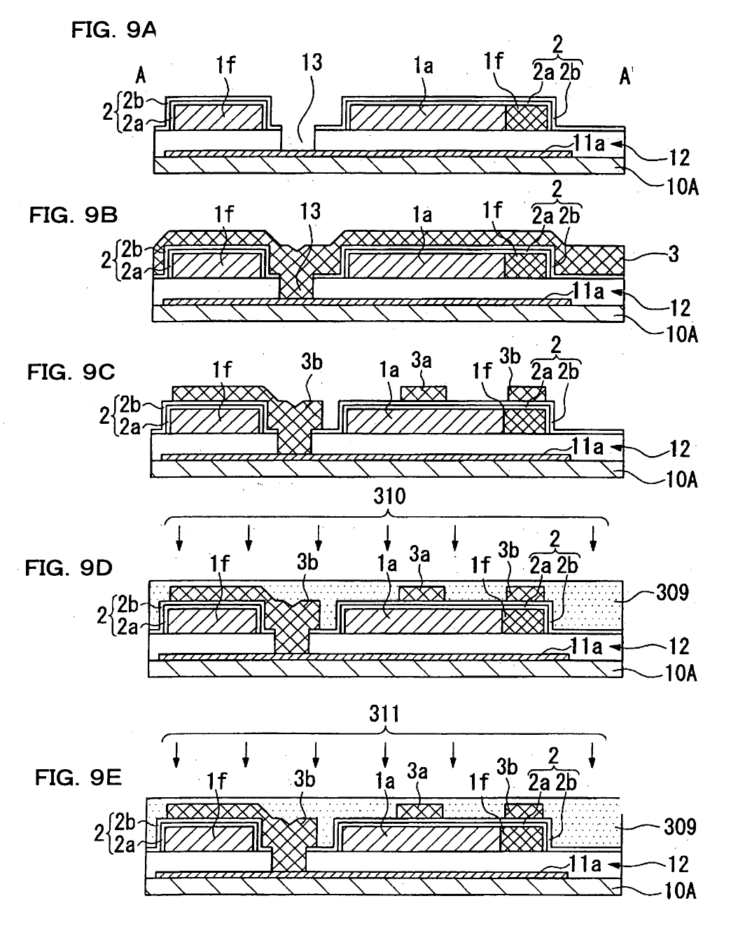

Next, as shown in FIG. 9A, a contact hole 13 reaching the light-shielding layer 11a is formed in the first interlayer insulating film 12 by dry etching processes, such as a reactive etching process, a reactive ion beam etching process, etc., or a wet etching process. At that time, if the contact hole 13 is formed by anisotropic etching processes, such as the reactive etching process, the reactive ion beam etching process, etc., there is an advantage that the contact hole can be formed substantially in the same shape as a mask. However, if the contact hole is formed by using both the dry etching and the wet etching, the contact hole 13 can be formed in a taper shape, so that it is possible to obtain an advantage that an open circuit in a wire connection can be reduced or prevented.

Next, as shown in FIG. 9B, a poly silicon layer 3 is deposited to be 350 nm thick by a low pressure CVD method, and then the poly silicon layer 3 is electrified by thermally diffusing phosphorous (P). Alternatively, a doped silicon film, into which P ions are implanted simultaneously with the formation of the poly silicon layer 3, may be used. As a result, it is possible to enhance the conductivity of the poly silicon layer 3. In order to enhance the conductivity of the poly silicon layer 3, a stacked structure obtained by depositing a simple metal substance, an alloy, metal silicide, and the like including at least one of Ti, W, Co, and Mo on the poly silicon layer 3 using a sputtering method, a CVD method, an electron-beam heating deposition method, etc., for example, with a thickness of 150 to 200 nm, may be used.

Next, as shown in FIG. 9C, the capacitor line 3b is formed together with the scanning line 3a having a predetermined pattern shown in FIG. 2 by a photolithography process and an etching process using a resist mask. Thereafter, poly silicon remaining in the backside of the substrate body 10A is etched and removed, with the surface of the substrate body 10A covered with a resist film.

Next, as shown in FIG. 9D, in order to form the P channel LDD regions of the TFT 31 for the driving circuit in the semiconductor layer 1a, in a state where the position corresponding to the N channel semiconductor layer 1a is covered with a resist film 309, dopants 310 of Group III element, such as B are doped thereto with a low concentration (for example, BF2 ions with an accelerating voltage of 90 keV and a dose of 3′ 1013/cm2) by using the gate electrode 3c as a diffusion mask, thereby forming the lightly doped source region 1g and the lightly doped drain region 1h of P channel.

Subsequently, as shown in FIG. 9E, in order to form the heavily doped source regions 1d and 1i, and the heavily doped drain regions 1e and 1j of P channel of the pixel switching TFT 30 and the TFT 31 for the driving circuit in the semiconductor layer 1a, in a state where the position corresponding to the N channel semiconductor layer 1a is covered with the resist film 309 and in a state (not shown) where a resist layer is formed on the scanning line 3a corresponding to the P channel by using a mask having a width larger than the scanning line 3a, dopants 311 of Group III element, such as B are similarly doped thereto with a high concentration (for example, BF2 ions with an accelerating voltage of 90 keV and a dose of 2′ 1015/cm2).

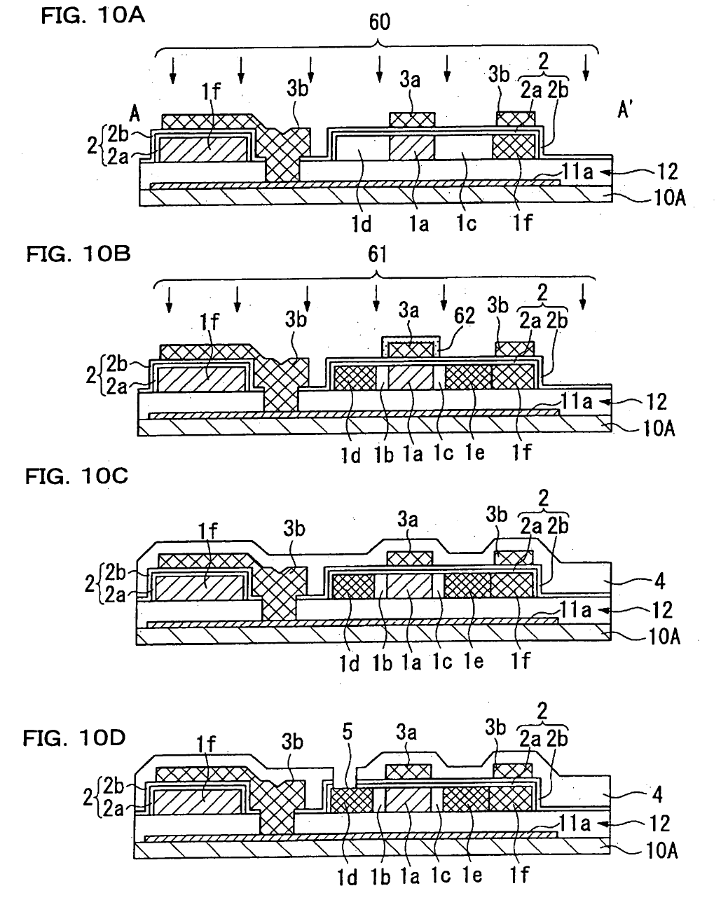

Next, as shown in FIG. 10A, in order to form the N channel LDD regions of the pixel switching TFT 30 and the TFT 31 for the driving circuit in the semiconductor layer 1a, in a state where the position corresponding to the P channel semiconductor layer 1a is covered with a resist film (not shown), dopants 60 of Group V element, such as P are doped thereto with a low concentration (for example, P ions with an accelerating voltage of 70 keV and a dose of 6′ 1012/cm1) by using the scanning line 3a (gate electrode) as a diffusion mask, thereby forming the lightly doped source regions 1b and 1g, and the lightly doped drain regions 1c and 1h of N channel.

Subsequently, as shown in FIG. 10B, in order to form the heavily doped source regions 1d and 1i and the heavily doped drain regions 1e and 1j of N channel of the pixel switching TFT 30 and the TFT 31 for the driving circuit in the semiconductor layer 1a, the resist 62 is formed on the scanning line 3a corresponding to the N channel by using a mask having a width larger than the scanning line 3a, and then dopants 61 of Group V element, such as P, are similarly doped thereto with a high concentration (for example, P ions with an accelerating voltage of 70 keV and a dose of 4′ 101 5/cm1).

Next, as shown in FIG. 10C, the second interlayer insulating film 4 composed of a silicate glass film, such as NSG, PSG, BSG, BPSG, and the like, a silicon nitride film, or a silicon oxide film is formed by, for example, the normal pressure or low pressure CVD method to cover the capacitor line 3b and the scanning line 3a. The thickness of the second interlayer insulating film 4 is preferably about 500 to 1500 nm, and more preferably about 800 nm.

Thereafter, in order to activate the heavily doped source regions 1d and 1i, and the heavily doped drain regions 1e and 1j, an annealing process of about 850° C. is carried out for twenty minutes.

Next, as shown in FIG. 10D, a contact hole 5 reaching the data line is formed by dry etching processes, such as a reactive etching process and a reactive ion beam etching process, or the wet etching process. Further, contact holes to connect the scanning line 3a or the capacitor line 3b to wiring lines (not shown) are formed in the second interlayer insulating film 4 by the same process as the process of the contact hole 5.

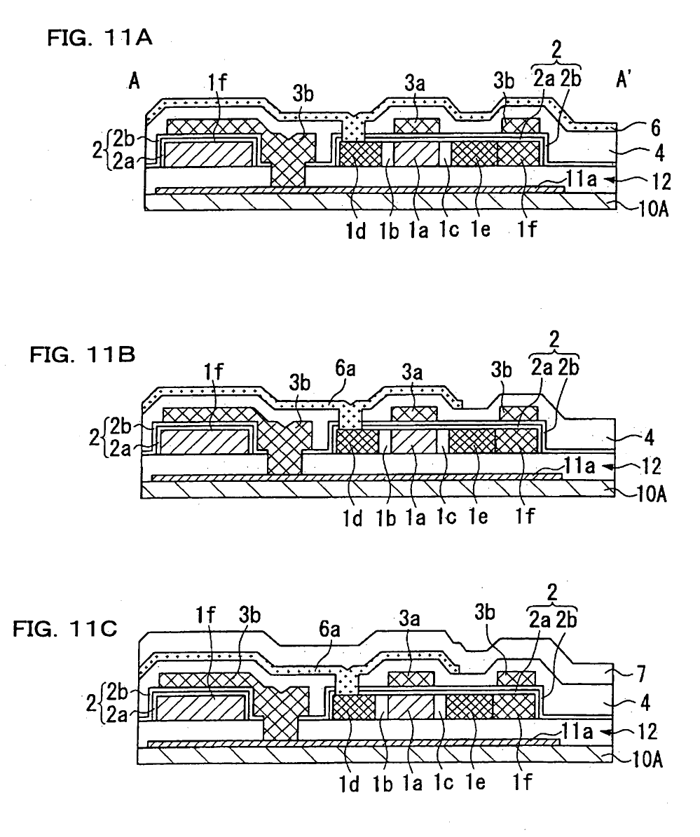

Next, as shown in FIG. 11A, a low-resistance metallic and light shielding material, such as Al or metal silicide, is deposited as the metal film 6 on the second interlayer insulating film 4 by a sputtering process to be about 100 to 700 nm thick, and preferably about 350 nm thick.

Furthermore, as shown in FIG. 11B, the data line 6a is formed by the photolithography process, the etching process, and so on.

Next, as shown in FIG. 11C, the third interlayer insulating film 7 composed of a silicate glass film, such as NSG, PSG, BSG, BPSG, and the like, a silicon nitride film, or a silicon oxide film is formed by, for example the normal pressure or low pressure CVD method to cover the data line 6a. The thickness of the third interlayer insulating film 7 is preferably about 500 to 1500 nm, and more preferably about 800 mm.

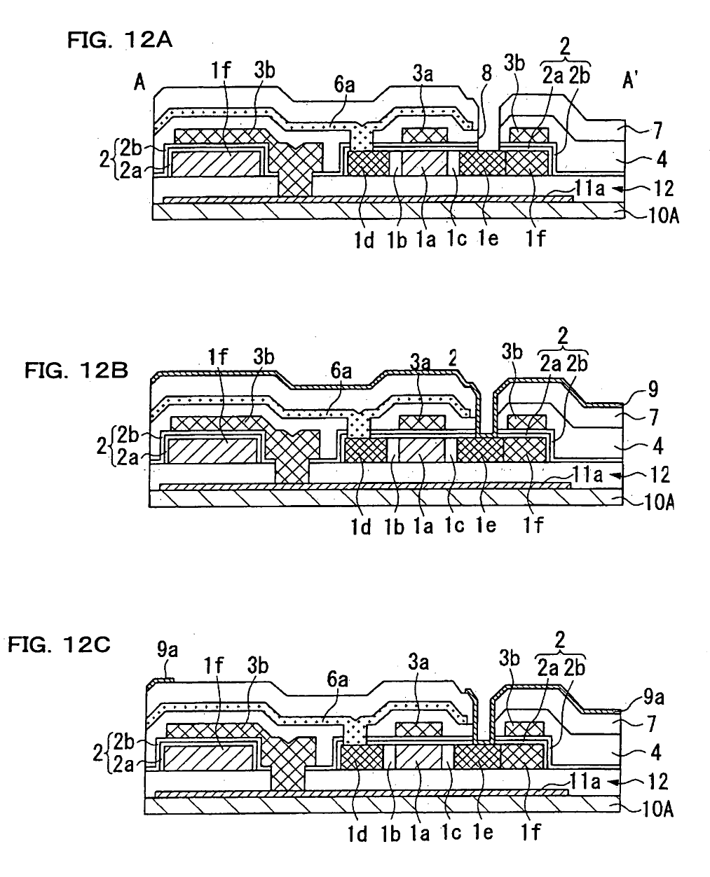

Next, as shown in FIG. 12A, the contact hole 8 to electrically connecting the pixel electrode 9a with the heavily doped drain region 1e in the pixel switching TFT 30 is formed by the dry etching processes, such as a reactive etching, a reactive ion beam etching, or the wet etching.

Next, as shown in FIG. 12B, a transparent conductive thin film 9, such as an ITO, is deposited to be about 50 to 200 nm thick on the third interlayer insulating film 7 by the sputtering process.

Furthermore, as shown in FIG. 12C, the pixel electrode 9a is formed using the photolithography process, the etching process, and so on. When the liquid crystal device according to this exemplary embodiment is a reflective liquid crystal device, the pixel electrode 9a may be made of an opaque material having high reflectivity, such as Al.

Subsequently, an alignment film 16 is formed by applying an application solution for an alignment film including polyimide on the pixel electrode 9a and then carrying out a rubbing process in a predetermined direction thereto to have a predetermined pre-tilt angle.

In this way, the TFT array substrate 10 is manufactured.

Next, a method of manufacturing the counter substrate 20 and a method of manufacturing a liquid crystal panel with the TFT array substrate 10 and the counter substrate 20 will be described.

For the counter substrate 20 shown in FIG. 2, a light-permeable substrate, such as a glass substrate is prepared as a substrate body 20A, a light-shielding film 23 and a light-shielding film 53 for shielding periphery thereof from lateral light are formed on a surface of the substrate body 20A. The light-shielding film 23 and the light-shielding film 53 for shielding the periphery thereof from lateral light are formed by sputtering metal materials, such as Cr, Ni, Al, and the like and then by carrying out the photolithography process and the etching process. The light-shielding films 23 and 53 may be made of a material, such as resin black, in which carbon or Ti is dispersed in the photoresist, in addition to the aforementioned metallic material.

Thereafter, a transparent conductive thin film, such as an ITO is deposited to be about 50 to 200 nm thick on the entire surface of the substrate body 20A by the sputtering method, thereby forming the counter electrode 21. Furthermore, an alignment film 22 is formed by applying an application solution for an alignment film including polyimide, etc. on the entire surface of the counter electrode 21 and then by carrying out a rubbing process in a predetermined direction thereto to have a predetermined pre-tilt angle.

In this way, the counter substrate 20 is manufactured.

Finally, the TFT array substrate 10 and the counter substrate 20 manufactured as described above are bonded to each other by the seal material 51 such that their alignment films 16 and 22 are opposite to each other. Then, the liquid crystal layer 50 having a predetermined thickness is formed by absorbing, for example, liquid crystal including a mixture of plural kinds of nematic liquid crystal into a space between both substrates using a vacuum absorption method. As a result, the liquid crystal panel having the aforementioned structure is obtained.

In the method of manufacturing the liquid crystal panel (electro-optical device), specifically in the method of manufacturing the pixel switching TFT 30 and the TFT 31 for the driving circuit, since the semiconductor layer 1a constituting the channel regions 1a′ (1k′) is formed of a monocrystalline silicon layer, the high-temperature process of 1000° C. or more having been necessary for the crystallization when the semiconductor layer 1a is composed of a polycrystalline silicon layer is not required.

Further, since the gate insulating film 2 is formed by forming the vapor-deposited insulating film 2b on the thermal oxide film 2a, the shoulder portion thereof (the upper portion on the shoulder portion 40a of the semiconductor layer 1a shown in FIG. 13) does not become extremely thinner than the other portions, so that sufficient dielectric strength can be ensured in the shoulder portion. Therefore, it is possible to reduce or prevent the gate dielectric breakdown in the shoulder portion by enhancing the dielectric strength in the shoulder portion. In addition, a parasitic transistor effect can be reduced, and the generation of defects can decrease since less stress is applied to the monocrystalline silicon layer.

Furthermore, in the process of forming the gate insulating film 2, since only a film formation process using a vapor deposition method is added thereto compared with the related art, the process is not complex. Thus, it is advantageous in cost, and the decrease of yield can be suppressed.

Furthermore, since the monocrystalline silicon layer is isolated using the mesa type isolation method, it is possible to easily form the monocrystalline silicon layer and to narrow the isolating area. Thus, the pixel switching TFT 30 or the TFT 31 for driving circuit including the transistor using the monocrystalline silicon layer can be formed well.

Furthermore, specifically in the transistor structure of the pixel switching TFT 30 or the TFT 31 for the driving circuit obtained as above, when a plurality of gate electrodes are formed on the semiconductor layer 1a, for example, like a double gate structure, the disadvantage of a short circuit between the gate electrodes 42 due to the etching residuals 42a as shown in FIGS. 16 and 17 can be reduced or prevented. That is, in an aspect of the present invention, since the thermal oxide film 2a is formed on the semiconductor layer 1a as shown in FIG. 13A and then the vapor-deposited insulating film 2b is formed thereon by the vapor deposition method as shown in FIG. 13B, the vapor-deposited insulating film 2b is formed also in a narrowed portion even when a lower end portion 2A of the side portion of the thermal oxide film 2a is narrowed. Thus, a largely recessed portion, in which the etching residuals can be easily generated, is not formed in the lower end portion 2A, and thus the short circuit between the gate electrodes 42 due to the etching residuals is reduced or prevented.

Furthermore, although the pixel switching TFT 30 in the liquid crystal panel according to this exemplary embodiment has the LDD structure, the lightly doped source region 1b and the lightly doped drain region 1c may be not provided, and an offset structure in which impurity ions are not implanted into the lightly doped source region 1b and the lightly doped drain region 1c may be employed. In addition, a self-aligned TFT, in which impurity ions are implanted thereto in high concentration by using the gate electrode as a mask to form the heavily doped source and drain regions in a self-alignment way, may be employed.

Furthermore, although a single gate structure, in which only one gate electrode composed of a part of the scanning line 3a of the pixel switching TFT 30 is provided between the source and drain regions, has been employed in the liquid crystal panel according to the present exemplary embodiment, two or more gate electrodes may be disposed therebetween. At that time, the same signal is applied to each of the gate electrodes. When a TFT is constructed to have dual gates (double gates) or triple or more gates, the leakage current in the junction portions of the channel and the source and drain regions can be reduced or prevented. Thus, it is possible to decrease the off current. Furthermore, when at least one of the gate electrodes is formed in the LDD structure or the offset structure, the off current can further decrease. Thus, it is possible to obtain a stable switching element. Furthermore, when two or more gate electrodes are disposed as described above, the short circuit between the gate electrodes 42 due to the etching residuals can be reduced or prevented as described above.

In addition, although the pixel switching TFT 30 has been formed in an N channel type in the liquid crystal panel according to this exemplary embodiment, it may be formed in a P channel type, and it may be formed in both the N channel type and the P channel type.

Furthermore, although the TFT 31 for the driving circuit has been provided in the non-display area of the TFT array substrate 10 in the liquid crystal panel according to the present embodiment, the TFT 31 for the driving circuit may not be provided in the non-display area, and it is not specifically limited.

Furthermore, although the semiconductor layer constituting the pixel switching TFT 30 and the semiconductor layer constituting the TFT 31 for the driving circuit have the same thickness in the liquid crystal panel according to the present exemplary embodiment, the thickness of the substrates may be different from each other.

Moreover, although the SOI technology is applied to the TFT array substrate 10 in the liquid crystal panel according to the present exemplary embodiment, the SOI technology may not be employed, and it is not specifically limited. In addition, a material to form the monocrystalline semiconductor layer is not limited to the monocrystalline silicon, and compound-based monocrystalline semiconductor may be used.

Furthermore, in the liquid crystal panel according to the present exemplary embodiment, a light-permeable substrate, such as a quartz substrate, a hard glass, and so on, has been used as the substrate body 10A of the TFT array substrate 10, and the light-shielding layer 11a to shield the pixel switching TFT 30 from light has been formed to reduce or prevent the light being incident on the pixel switching TFT 30, thereby suppressing the light leakage current. However, a non-permeable substrate body 10A as the substrate body 10A may be used, and in this case, the light shielding layer 11a may be omitted.

In addition, although the capacitor line 3b, which is a wiring line to form a capacitor between the semiconductor layers, has been provided in order to form the storage capacitor 70 in the liquid crystal panel according to the present exemplary embodiment, a capacitor may be formed between the pixel electrode 9a and the pre-stage scanning line 3a, without providing the capacitor line 3b. Alternatively, another storage capacitor electrode may be formed on the capacitor line 3b with a thin insulating film therebetween without forming the first storage capacitor electrode 1f.

Furthermore, the pixel electrode 9a and the heavily doped drain region 1e may be electrically connected through the same Al film as the data line 6a or the same poly silicon film as the scanning line 3a.

Moreover, although the light-shielding layer 11a has been connected to the poly silicon film 3, the contact hole thereof may be formed simultaneously with the formation of the contact hole 5 reaching the data line shown in FIG. 10D to be connected to the metal film 6. In addition, in order to fix the electric potential of the light shielding layer 11a, the electrical contact may not be implemented on every pixel as described above, but may be implemented in a bundle in the periphery of the pixel area.

Furthermore, in the liquid crystal panel according to the present exemplary embodiment, a test circuit to test the quality, defects, and the like of the liquid crystal device at the time of the manufacture or the shipment of the liquid crystal device may be formed on the TFT array substrate 10.

Furthermore, a driving LSI mounted on a TAB (Tape Automated Bonding) substrate may be electrically and mechanically connected through an anisotropic conductive film provided in the peripheral portions of the TFT array substrate 10 without providing the data line driving circuit 101 and the scanning line driving circuits 104 on the TFT array substrate 10.

Moreover, a surface of the counter substrate 20, on which projection light is incident, or a surface of the TFT array substrate 10, from which emission light is emitted, may be provided with a polarizing film, a retardation film, polarizing device, and the like in a predetermined direction depending upon operation modes, such as a TN (Twisted Nematic) mode, a VA (Vertically Aligned) mode, a PDLC (Polymer Dispersed Liquid Crystal) mode, and so on, or depending upon a normally-white mode/normally-black mode.

In addition, the liquid crystal panel as the electro-optical device including the transistor according to an aspect of the present invention can be applied to a reflective liquid crystal panel and a transmissive liquid crystal panel.

The above liquid crystal panel can be applied to, for example, a color liquid crystal projector (a projection display device). In this case, three liquid crystal panels are employed as light valves for R, G, and B colors, respectively, and color light components separated by dichroic mirrors to separate R, G, and B colors are incident as projection light on the light valves, respectively. Therefore, in the above exemplary embodiment, a color filter is not provided in the counter substrate 20. However, in predetermined areas facing the pixel electrodes 9a in which the light-shielding films 23 are not formed, R, G, and B color filters may be formed on the counter substrate 20 together with its protection film. In this way, the liquid crystal panels according to the respective exemplary embodiments can be applied to a color liquid crystal device, such as a direct-view or reflective color liquid crystal television in addition to the liquid crystal projector.

Furthermore, micro lenses may be formed on the counter substrate 20 such that one micro lens corresponds to one pixel. As a result, the concentration efficiency of incident light is enhanced, and it is thus possible to realize a bright liquid crystal panel. Moreover, dichroic filters of producing RGB colors may be formed using light interference by depositing several interference layers different in refractive index on the counter substrate 20. By using the counter substrate having the dichroic filters, it is possible to realize a brighter color liquid crystal device.

In addition, the electro-optical device including the transistor according to an aspect of the present invention is not limited to the aforementioned liquid crystal panel, but may be applied to an organic electroluminescence device, an electrophoresis device, a plasma display device, and the like.

Furthermore, a semiconductor device according to an aspect of the present invention includes a transistor of which the gate insulating film 2 has a stacked structure of at least two layers of the thermal oxide film 2a formed through the thermal oxidation of the monocrystalline silicon layer (monocrystalline semiconductor layer) and the vapor-deposited insulating film 2b, such as the aforementioned pixel switching TFTs 30, and may be applied to any semiconductor device such as a memory, only if it has such a transistor.

Electronic Apparatus

An example of an electronic apparatus including the liquid crystal panel obtained through the manufacturing method according to the above exemplary embodiments will be described.

FIG. 14 is a perspective view illustrating a mobile phone as an example of the electronic apparatus employing the electro-optical devices (liquid crystal device) according to the above exemplary embodiments. In FIG. 14, a reference numeral 1000 denotes a mobile phone body, and a reference numeral 1001 denotes a liquid crystal display unit employing the aforementioned liquid crystal device.

Since the electronic apparatus (mobile phone) shown in FIG. 15 includes the liquid crystal device according to the above exemplary embodiment, it is possible to realize an electronic apparatus having an excellent display unit with high reliability.

Furthermore, the electronic apparatus according to an aspect of the present invention can be applied to, for example, a projection display apparatus, a wristwatch type electronic apparatus having a liquid crystal display unit employing the above liquid crystal display device, a portable information processing apparatus, such as a word processor and a personal computer, in addition to the mobile phone.

A technical scope of the present invention is riot limited to the exemplary embodiments described above, but modifications and changes may be made thereto without departing from the spirit of the present invention.

What is claimed is:

1. A transistor, comprising:
at least a monocrystalline semiconductor layer and a gate insulating film provided on the monocrystalline semiconductor layer,
the gate insulating film having a thermal oxide film formed on the monocrystalline semiconductor layer and at least one vapor-deposited insulating film formed on the thermal oxide film.

2. The transistor according to claim 1, the monocrystalline semiconductor layer being made of monocrystalline silicon.

3. The transistor according to claim 1, the monocrystalline semiconductor layer being a mesa type.

4. The transistor according to claim 1, the monocrystalline semiconductor layer having a thickness of 15 to 60 nm.

5. The transistor according to claim 1, the thermal oxide film of the gate insulating film having a thickness of 5 to 50 nm.

6. A method of manufacturing a transistor in which a channel region and source and drain regions are formed in a monocrystalline semiconductor layer and a gate electrode is formed on the monocrystalline semiconductor layer with a gate insulating film therebetween, the method comprising:
forming the gate insulating film including at least thermally oxidizing the monocrystalline semiconductor layer to form a thermal oxide film on a surface of the monocrystalline semiconductor layer; and
forming a vapor-deposited insulating film on the thermal oxide film using a vapor deposition method.

7. The method of manufacturing a transistor according to claim 6, thermally oxidizing the monocrystalline semiconductor layer to form the thermal oxide film on the surface of the monocrystalline semiconductor layer being carried out by using both a dry thermal oxidation process and a wet thermal oxidation process.

8. An electro-optical device, comprising:
a transistor according to claim 1.

9. An electro-optical device in which an electro-optical material is interposed between a pair of substrates facing each other,
a transistor according to claim 1 being provided as a switching element in a display area.

10. A semiconductor device, comprising:
a transistor according to claim 1.

11. An electronic apparatus, comprising:
an electro-optical device according to claim 8.

12. An electro-optical device, comprising:
a transistor obtained by the manufacturing method of claim 6.

13. An electro-optical device in which an electro-optical material is interposed between a pair of substrates facing each other, a transistor obtained by the manufacturing method according to claim 6 being provided as a switching element in a display area.

14. A semiconductor device, comprising:
a transistor obtained by the manufacturing method according to claim 6.

15. An electronic apparatus, comprising:
a semiconductor device according to claim 10.
